(19) United States
(12) Patent Application Publication
(10) Pub. No.: US 2026/0353686 A1
(43) Pub. Date: Nov. 5, 2026

(54) INSULATED GATE BIPOLAR TRANSISTOR DESIGN AND METHODS

(71) Applicant: SEMICONDUCTOR COMPONENTS INDUSTRIES, LLC, Scottsdale, AZ (US)

(72) Inventors: Mingjiao LIU, Gilbert, AZ (US); Prasad VENKATRAMAN, Gilbert, AZ (US)

(73) Assignee: SEMICONDUCTOR COMPONENTS INDUSTRIES, LLC, Scottsdale, AZ (US)

(21) Appl. No.: 19/197,519

(22) Filed: May 2, 2025

(51) Int. Cl. H10D 12/00; H10D 12/01

(52) U.S. Cl. CPC H10D 12/481; H10D 12/038

(57) ABSTRACT

An insulated gate bipolar transistor includes multiple semiconductor layers, multiple mesas, multiple contact regions and an electrically insulative layer. The semiconductor layers (i) include a well layer that defines a semiconductor surface and (ii) define multiple first type trenches and multiple second type trenches through the semiconductor surface and into at least the well layer. The mesas (i) are separate the first trenches and the second type trenches and (ii) each includes a sidewall that faces a corresponding one of the second type trenches. The contact regions are (i) of a first dopant type and (ii) formed in one or more of the sidewalls within each respective second type trench of the multiple second type trenches. The electrically insulative layer (i) is formed over the semiconductor surface and (ii) defines multiple openings aligned with the contact regions.

### INTRODUCTION

High-voltage Insulated Gate Bipolar Transistors (IGBT) are used in medium to high power electronic systems, like in industrial drives, uninterruptible power supplies (UPS), renewables, electric cars, and traction motors. Progress in increased power densities has been achieved by reducing on-state and switching losses, increasing current densities, and maximum junction temperatures. As wide band gap (WBG) semiconductors such as Gallium Nitride (GaN) and Silicon Carbide (SiC) gain favor in the power semiconductor market, IGBT designs are being considered as possible competition to the WBG solutions.

Accordingly, those skilled in the art continue with research and development efforts in the field of silicon-based field-stop insulated gate bipolar transistors with narrow mesas.

### SUMMARY

An insulated gate bipolar transistor (IGBT) is provided herein. The IGBT includes multiple semiconductor layers that (i) include a well layer that defines a semiconductor surface and (ii) define multiple first type trenches and multiple second type trenches through the semiconductor surface and into at least the well layer. The IGBT includes multiple mesas that (i) separate the first type trenches and the second type trenches and (ii) each includes a sidewall that faces a corresponding one of the second type trenches. Multiple contact regions of a first dopant type are formed in one or more of the sidewalls within each respective second type trench of the multiple second type trenches. An electrically insulative layer (i) is formed over the semiconductor surface and (ii) defines a plurality of openings aligned with the plurality of contact regions.

The above summary is not intended to represent every embodiment or aspect of the present disclosure. Rather, the foregoing summary exemplifies certain novel aspects and features as set forth herein. The above noted and other features and advantages of the present disclosure will be readily apparent from the following detailed description of representative embodiments and modes for carrying out the present disclosure when taken in connection with the accompanying drawings and the appended claims.

### BRIEF DESCRIPTION OF THE DRAWINGS

The drawings described herein are for illustrative purposes only, are schematic in nature, and are intended to be exemplary rather than to limit the scope of the disclosure.

FIG. 1 is a schematic cross-sectional diagram of an insulated gate bipolar transistor (IGBT) in accordance with one or more exemplary embodiments.

FIG. 2 is a schematic plan diagram of another IGBT in accordance with one or more exemplary embodiments.

FIG. 3 is an electrical schematic diagram of the IGBT in accordance with one or more exemplary embodiments

FIG. 4 is a schematic cross-sectional diagram of starting semiconductor material for fabricating the IGBT in accordance with one or more exemplary embodiments.

FIG. 5 is a schematic cross-sectional diagram of fabricating trenches in the IGBT in accordance with one or more exemplary embodiments.

FIG. 6 is a schematic cross-sectional diagram of fabricating an electrically insulating coating/layer and the trench material in the IGBT in accordance with one or more exemplary embodiments.

FIG. 7 is a schematic cross-sectional diagram of further trench formation in the IGBT in accordance with one or more exemplary embodiments.

FIG. 8 is a schematic cross-sectional diagram of fabricating interlayer dielectric covers in the IGBT in accordance with one or more exemplary embodiments.

FIG. 9 is a schematic cross-sectional diagram of fabricating contacts in the IGBT in accordance with one or more exemplary embodiments.

FIG. 10 is a schematic cross-sectional diagram of fabricating an emitter conductive layer in the IGBT in accordance with one or more exemplary embodiments.

The present disclosure may be modified or embodied in alternative forms, with representative embodiments shown in the drawings and described in detail below. Inventive aspects of the present disclosure are not limited to the disclosed embodiments. Rather, the present disclosure is intended to cover alternatives falling within the scope of the disclosure as defined by the appended claims.

### DETAILED DESCRIPTION

Embodiments of the disclosure generally provide silicon-based field-stop (FS) insulated gate bipolar transistor (IGBT) designs and fabrication methods. The designs and/or methods reduce a distance between trenches (e.g., gate trenches and/or emitter trenches) formed into a semiconductor substrate. The reduced distances are comparable with a thickness of an inversion layer. The inversion layer may reside in a high-concentration n-type (n⁺ ) semiconductor that also serves as a hole barrier. The trenches are separated by very narrow mesas (e.g., no wider than 0.5 micrometers (um) apart). Contacts to the narrow mesas are provided across the trenches. Dry etching with accurate alignment may achieve such mesas and contacts. The resulting structures generally achieve a high injection effect and a high conduction modulation in an IGBT drift region. The structure may also produce a low forward drop in the IGBT.

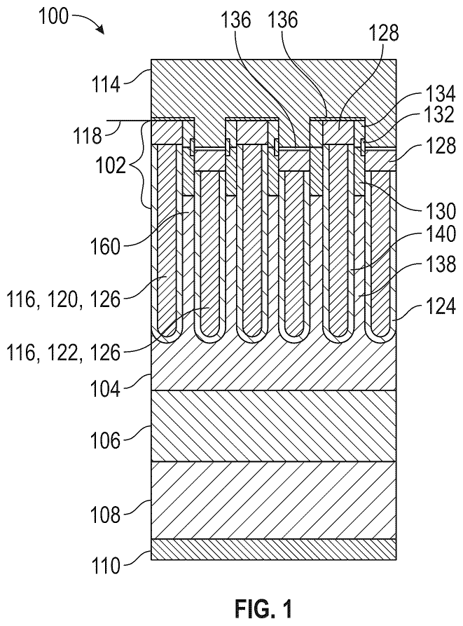

Referring to FIG. 1, a schematic cross-sectional diagram of an example implementation of an insulated gate bipolar transistor (IGBT) 100 is shown in accordance with one or more exemplary embodiments. The IGBT 100 generally includes multiple semiconductor layers including at least a first doped layer 102 (or “first layer” for short), a second doped layer 104 (or “second layer” for short), a third doped layer 106 (or “third layer” for short), and a forth doped layer 108 (or “fourth layer” for short). Multiple electrically conductive layers 110 and 114 are used to interconnect features of the IGBT 100.

In various embodiments, the first doped layer 102 may initially be fabricated as a low-doped semiconductor layer or an intrinsic semiconductor layer. During subsequent fabrication steps, the first doped layer 102 may become lightly doped as a p⁻ layer or doped as a p layer. In some embodiments, the first doped layer 102 may form a p-well layer within the first doped layer 102.

The second doped layer 104 is lightly doped n⁻ layer. The second doped layer 104 may provide a drift region of the IGBT 100. In various embodiments, the second doped layer 104 may be formed as an epitaxial layer on the third doped layer 106.

The third doped layer 106 is a heavily doped n⁺ layer. The third doped layer 106 may initially be a semiconductor wafer. The wafer is generally a silicon wafer. The third doped layer 106 generally forms a buffer layer.

The fourth doped layer 108 is a heavily doped p⁺ layer. The fourth doped layer 108 is deposited or formed on the backside of the third doped layer 106 after the third doped layer 106 is thinned (e.g., wafter thinning). The fourth doped layer 108 may be created either through deposition or implantation. The fourth doped layer 108 implements a collector layer of the IGBT 100.

The collector conductive layer 110 is formed in contact with the fourth doped layer 108. The collector conductive layer 110 is generally a metal (e.g., aluminum, gold, or other conductive metal), a polysilicon layer, or other conductive material. The collector conductive layer 110 generally forms the collector node of the IGBT 100.

The emitter conductive layer 114 may be a metal (e.g., aluminum, gold, or other conductive metal), a polysilicon layer, or other conductive material. The emitter conductive layer 114 forms the emitter node of the IGBT 100.

Multiple trenches 116 are formed through the first doped layer 102 and into the second doped layer 104 extending from a semiconductor surface 118 toward the third doped layer 106. Some of the trenches 116 form first type trenches 120 for the gates of the IGBT 100. Other trenches 116 form second type trenches 122 for the emitters of the IGBT 100. In various embodiments, the trenches 116 as illustrated may be solely first (e.g., gate) type trenches 120.

Each trench 116 has an inner wall that is coated/layered with an electrically insulative coating/layer 124. The electrically insulative coating/layer (or insulating sidewall) 124 may be silicon dioxide (SiO₂). The electrically insulative coating/layer 124 provides electrical isolation between the first type trenches 120 and the second type trenches 122 from the surrounding first doped layer 102 and the second doped layer 104. Other electrically insulating materials may be used to meet the design criteria of a particular application.

A trench material 126 is disposed in and fills each trench 116. The trench material 126 may be an electrical conductor, a metal, a doped polysilicon material, and/or the like.

An interlayer dielectric 128 (ILD) cover the trench materials 126 in each trench 120 and 122. The interlayer dielectric 128 provides electrical isolation between the trench materials 126 and the emitter conductive layer 114. Other electrically insulating materials may be used to meet the design criteria of a particular application.

Mesas 160 are formed between a combination of the first type trenches 120 and the second type trenches 122. In various embodiments, each mesa 160 may have a narrow width that is no greater than 0.5 um. In various embodiments, the width may be approximately 0.16 um. Since the emitter conductive layer 114 is deposited on the mesas 160 and stretches over the second (e.g., emitter) type trenches 122, each mesa 160 makes contact to the emitter conductive layer 114 (e.g., no “floating” mesas).

Well regions 130 are formed in the first layer 102 in the mesas 160 between the emitter conductive layer 114 and the second layer 104. In various embodiments, the well regions 130 are lightly doped as a p⁻ layer or doped as a p layer.

Contact regions 132 are formed in a sidewall of the mesas 160 and extend into the p-wells 130. The contact regions 132 are heavily doped p+regions (e.g., first dopant type) to form good direct ohmic contacts between the emitter conductive layer 114 and the p-wells 130. In various embodiments, the contact regions 132 are formed by ion implantation or diffusion.

Buffer regions 134 are formed in the mesas 160 and adjoin the semiconductor surface 118. The buffer regions 134 are heavily doped n⁺ regions (e.g., second dopant type) that provide additional direct ohmic contacts between the emitter conductive layer 114 and the p-wells 130. The second dopant type of the buffer regions 134 are generally of an opposite charge carrier type as the first dopant type of the contact regions 132. The buffer regions 134 may be referred to as the emitter of the insulated gate bipolar transistor 100 and provides electrons to the draft regions.

An optional electrically insulating layer 136 is deposited over the first layer 102. The electrically insulating layer 136 may be silicon dioxide (SiO₂). Other electrically insulating materials may be used to meet the design criteria of a particular application.

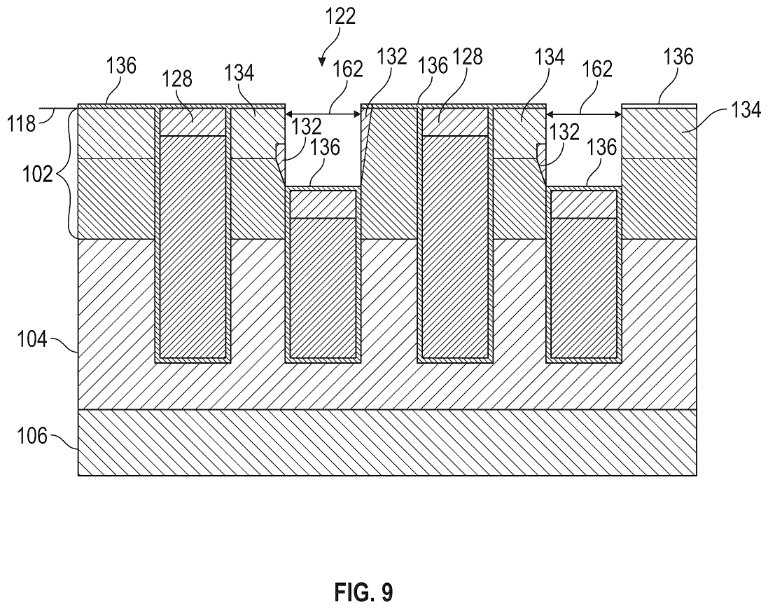

The electrically insulating layer 136 is patterned to cover over the semiconductor surface 118 and the interlayer dielectrics 128 for protection and electrical isolation. The sidewalls 162 (FIG. 9) are cleared of the electrically insulating layer 136 to expose and provide for direct electrical contact for the contact regions 132 and the buffer regions 134 with the emitter conductive layer 114.

Drift regions 138 exist in the second doped layer 104 between the first type trenches 120 and the second type trenches 122. The electrically insulative coating/layer 124 adjoining the firs (e.g., gate)t type trenches 120 in the first doped layer 102 act as gate oxides 140. While the gates are positively biased, inversion layers are formed near the gate oxides 140 in the first doped layer 102. The inversion layers act as a barrier to holes and enhances the conduction modulation of the holes in the drift regions 138. As such, the insulated gate bipolar transistor 100 is characterized by a lack of hole storage regions under the first doped well layer 102 in the mesas 160 (e.g., in the second doped layer 104 under the p-wells 130). The holes are introduced into the drift regions 138 from the collector conductive layer 110. A plasma concentration under the trenches 116 is generally higher for narrow mesa (e.g., <0.5 um) designs than that of wider mesa (e.g., >0.7 um) designs during an on-state of the transistor, that reduces the conduction loss.

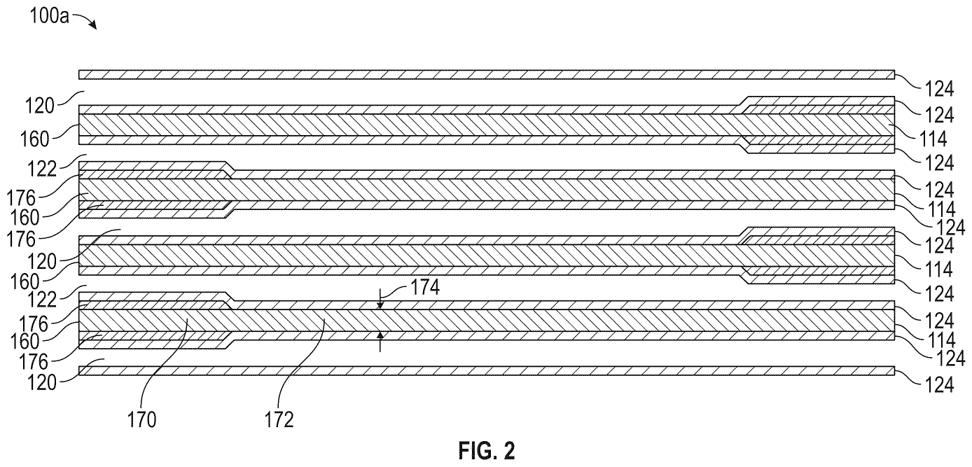

Referring to FIG. 2, a schematic plan diagram of an example implementation of the IGBT 100a is shown in accordance with one or more exemplary embodiments. The IGBT 100a may be a variation of the IGBT 100. The figure illustrates a design in which the trenches alternate between first type trenches 120 and second type trenches 122. In other designs, a sequence of trenches may be first type trench 120, second type trench 122, second type trench 122, first type trench 120, second type trench 122, and the like. Other sequences and numbers of the trenches may be implemented to meet the design criteria of a particular application.

The mesas 160 may include a wide portion 170 and a narrow portion 172. The narrow portions 172 may be no greater than 0.5 um wide. The wide portions 170 may be approximately 0.7 to 1.0 um wide. Other dimensions of the wide portions 170 may be implemented to meet the design criteria of a particular application.

The emitter conductive layers 114 are created on each mesa 160 and extend into the second type trenches 122. In various embodiments, the emitter conductive layer 114 may be doped p⁺ for good contact. A width 174 of the emitter conductive layers 114 may be consistent across the mesas 160. The n⁺ regions 176 may be limited to the wide portions 170.

In various embodiments, emitter conductive layers 114 do not overlap the electrically insulative coating/layer 124. Therefore, n⁺ regions 176 may exist in the wide portions 170 between the emitter conductive layers 114 and the electrically insulative coating/layer 124.

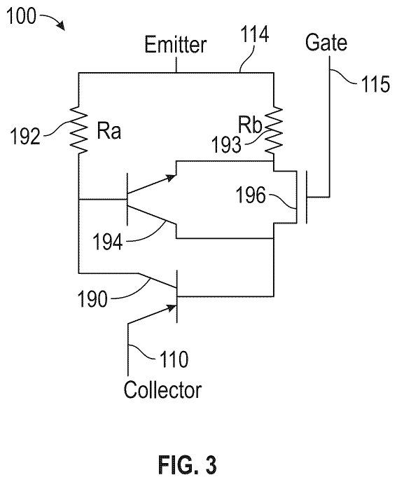

Referring to FIG. 3, an electrical schematic diagram of the IGBT 100 is shown in accordance with one or more exemplary embodiments. A first (PNP) transistor 190 and a series resistance 192 (Ra) are created by the layers 102-108 between the collector conductive layer 110 and the emitter conductive layer 114. A second (NPN) transistor 194 and a ballast resistor 193 are formed between a base of the first transistor 190 and the emitter conductive layer 114 (emitter node of the IGBT). A base of the second transistor 194 is connected to the collector of the first transistor 190. A third metal oxide semiconductor (MOS) transistor 196 is formed between the ballast resistor 193 and the base of the first transistor 190. A gate of the third transistor 196 is the gate node 115 of the IGBT 100.

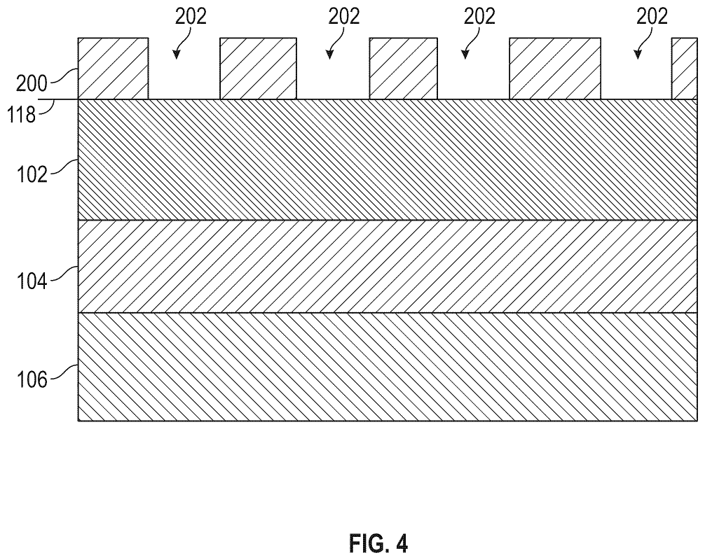

Referring to FIGS. 4-10, schematic cross-sectional diagrams of an example method of fabricating the IGBT 100 is shown in accordance with one or more exemplary embodiments. The sequence of steps are shown as a representative example. Other step orders may be implemented to meet the criteria of a particular application.

Referring to FIG. 4, a schematic cross-sectional diagram of the starting semiconductor material for fabricating the IGBT 100 is shown in accordance with one or more exemplary embodiments.

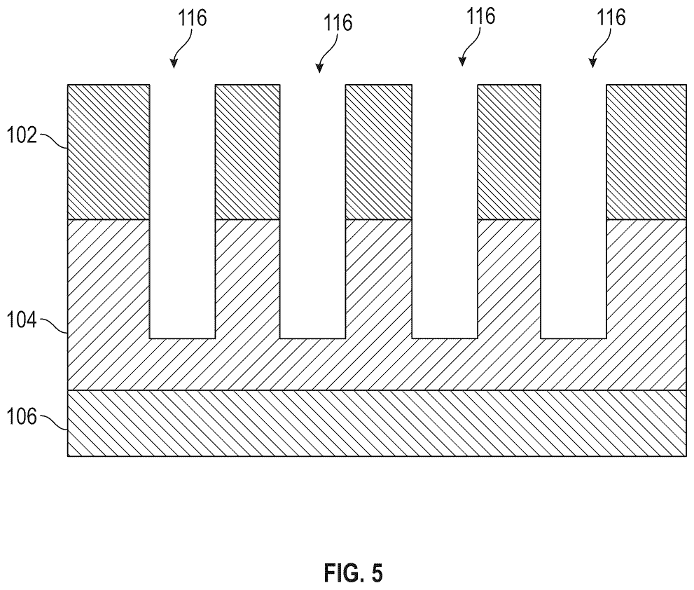

The doped layers 102, 104, and 106 are initially formed in a stacked/layered configuration with an oxide mask layer 200 coupled with first doped layer 102 at the semiconductor surface 118. Note that the first doped layer 102 may not begin as a p⁻ semiconductor layer, but may be altered later in the fabrication to be a lightly-doped p⁻ or a p doped semiconductor layer. The oxide mask layer 200 is subsequently patterned to form vias 202 over the trenches 116 (see FIG. 5).

In various embodiments, the first doped layer 102 may be formed after the trenches 116 are formed in the second doped payer 104. In some embodiments, the third doped layer 106 may be formed before or after the frontend.

Referring to FIG. 5, a schematic cross-sectional diagram of the IGBT 100 with the trenches is shown in accordance with one or more exemplary embodiments.

The trenches 116 are formed by etching into the first doped layer 102 through the semiconductor surface 118 and the patterns in the oxide mask layer 200 (FIG. 4). The etching may be achieved by dry etching with accurate alignment to produce the narrow mesas.

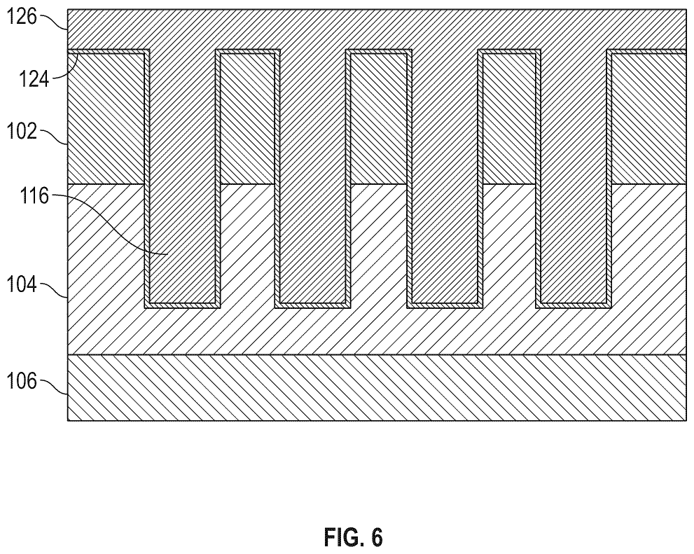

Referring to FIG. 6, a schematic cross-sectional diagram of the IGBT 100 with the electrically insulating coating/layer and the trench material is shown in accordance with one or more exemplary embodiments.

The oxide mask layer 200 may then be removed and the electrically insulative coating/layer 124 is grown. Thereafter, the trench material 126 is deposited to fill the trenches 116.

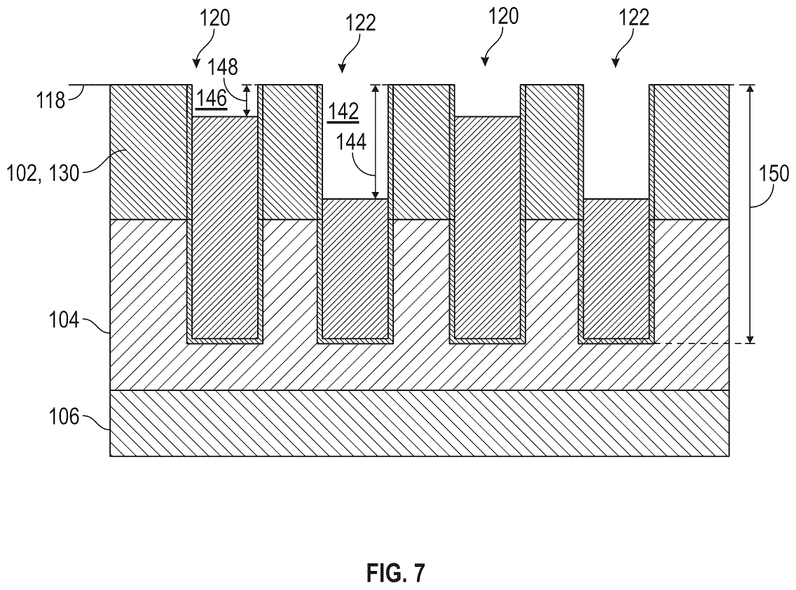

Referring to FIG. 7, a schematic cross-sectional diagram of further trench formation is shown in accordance with one or more exemplary embodiments.

For embodiments that implement emitter trenches, after the excess trench material 126 has been removed, additional trenches 142 are formed through the semiconductor surface 118 into the first layer 102 and aligned the second (e.g., emitter) type trenches 122. The additional trenches 142 may start below the semiconductor surface 118 and extend to the trench depth 144 below the semiconductor surface 118 to expose an area where the contact regions 132 will be formed. The trench depth 144 of each additional trench 142 is shallower than a well depth 150 of the second type trench 122.

In various embodiments, optional other trenches 146 may be formed through the semiconductor surface 118 into the first layer 102 and aligned the first (e.g., gate) type trenches 120. The other trenches 146 may start below the semiconductor surface 118 and extend to the other trench depth 148 below the semiconductor surface 118. The trench depth 148 of the other trenches 146 is shallower than a well depth 150 of the first type trench 120.

Masks may be used to define the additional trenches 142 and 146 in alignment with the second type trenches 122 and the first type trenches 120. Dry etching may be used to remove some of the trench material 126 from the second type trenches 122 and the first type trenches 120. In some embodiments where the optional other trenches 146 are not implemented, the trench material 126 in the first type trenches 120 may be unchanged.

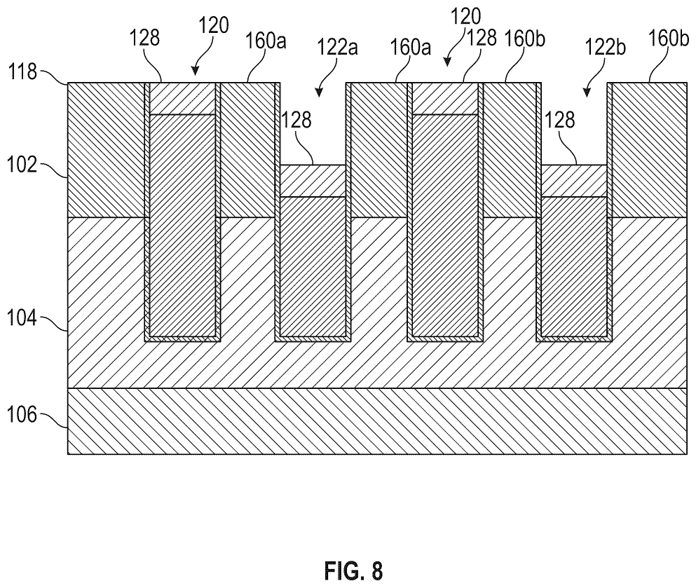

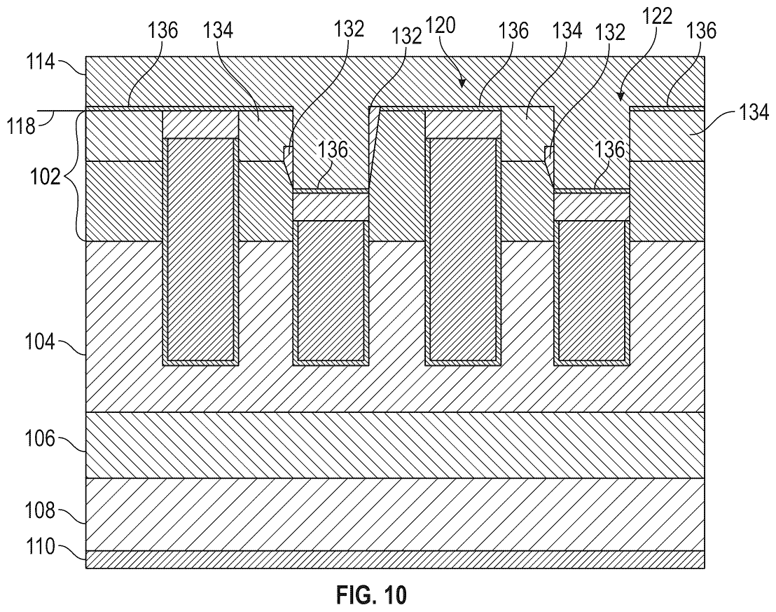

Referring to FIG. 8, a schematic cross-sectional diagram of the ILD covers is shown in accordance with one or more exemplary embodiments. The interlayer dielectric 128 covers the trench materials 126 in each trench 120 and 122. The interlayer dielectric 128 provides electrical isolation between the trench materials 126 and the emitter conductive layer 114 (FIG. 10).

Referring to FIG. 9, a schematic cross-sectional diagram of the contacts is shown in accordance with one or more exemplary embodiments. FIG. 9 generally illustrates an implementation with the p⁺ contact regions 132 and the n⁺ buffer regions 134. In various embodiments, the contact regions 132 may be formed in two facing sidewalls 162 of a second (e.g., emitter) type trench 122a, as illustrated. In some embodiments, a single contact region 132 may be form in a single sidewalls 162 of a second type trench 122b. In various embodiments, the buffer regions 134 may be formed in both mesa 160b pairs around a second type trench 122b. In other embodiments, a single buffer region 134 may be formed in a single one of the mesa 160a pairs around a second type trench 122a.

After the contact regions 132 and the buffer regions 134 are formed, the first type trenches 120, the second type trenches 122, and the remaining semiconductor surface 118 may be covered and patterned with the additional electrically insulating layer 136. The sidewalls 162 are cleared of the electrically insulating layer 136 to provide for electrical contact for the contact regions 132 and the buffer regions 134 with the emitter conductive layer 114 (FIG. 10).

Referring to FIG. 10, a schematic cross-sectional diagram of the emitter conductive layer is shown in accordance with one or more exemplary embodiments.

An additional electrically insulative layer (not shown) is generally formed over the semiconductor surface 118. In some embodiments, the electrically insulating layer 136 is patterned to create openings over the second type trenches 122 thereby allowing full contact of the contact regions 132 and buffer regions 134 in the sidewalls 162 of the mesas 160 (FIG. 9). The emitter conductive layer 114 is deposited over the electrically insulating layer 136 and into the second type trenches 122. In the second type trench 122, the emitter conductive layer 114 forms electrical connections with the contact regions 132 and buffer regions 134.

After wafer thinning of the third doped layer 106, the fourth doped layer 108 is disposed on the back side third doped layer 106. The collector conductive layer 110 is deposited on the back side of the fourth doped layer 108.

These and other benefits of the present teachings will be readily appreciated by those skilled in the art now having the benefit of the foregoing disclosure. While several modes for carrying out the many aspects of the present teachings have been described in detail, those familiar with the art to which these teachings relate will recognize various alternative aspects for practicing the present teachings that are within the scope of the appended claims. The above description and accompanying drawings are illustrative and exemplary of the entire range of alternative embodiments that an ordinarily skilled artisan would recognize as implied by, structurally and/or functionally equivalent to, or otherwise rendered obvious based upon the included content, and not as limited solely to those explicitly depicted and/or described embodiments. Moreover, the present concepts expressly include combinations and sub-combinations of the described elements and features. The detailed description and the drawings are supportive and descriptive of the present teachings, with the scope of the present teachings defined solely by the claims.

What is claimed is:

1. An insulated gate bipolar transistor, comprising:
a plurality of semiconductor layers that (i) include a well layer that defines a semiconductor surface and (ii) define a plurality of first type trenches and a plurality of second type trenches through the semiconductor surface and into at least the well layer;
a plurality of mesas that (i) separate the plurality of first type trenches and the plurality of second type trenches and (ii) each includes a sidewall that faces a corresponding one of the plurality of second type trenches;
a plurality of contact regions (i) of a first dopant type and (ii) formed in one or more of the sidewalls within each respective second type trench of the plurality of second type trenches; and
an electrically insulative layer (i) formed over the semiconductor surface and (ii) defines a plurality of openings aligned with the plurality of contact regions.

2. The insulated gate bipolar transistor according to claim 1, further comprising:
a plurality of buffer regions of a second dopant type (i) formed in the plurality of mesas and (ii) extend away from the semiconductor surface into the well layer, wherein the second dopant type and the first dopant type are opposite charge carrier types.

3. The insulated gate bipolar transistor according to claim 1, wherein:
the plurality of semiconductor layers further define a plurality of additional trenches formed through the semiconductor surface into the well layer and aligned the plurality of second type trenches.

4. The insulated gate bipolar transistor according to claim 3, wherein:
the well layer has a well depth;
a trench depth of each of the plurality of additional trenches is shallower than the well depth; and
the plurality of additional trenches expose the contact regions in the plurality of mesas.

5. The insulated gate bipolar transistor according to claim 3, further comprising:
a trench material disposed in the plurality of second type trenches.

6. The insulated gate bipolar transistor according to claim 5, wherein:
the electrically insulative layer covers the trench material.

7. The insulated gate bipolar transistor according to claim 5, wherein:
the electrically insulative layer isolates the trench material from the plurality of semiconductor layers.

8. The insulated gate bipolar transistor according to claim 4, further comprising:
an emitter conductive layer that extends into and across each of the plurality of additional trenches.

9. The insulated gate bipolar transistor according to claim 8, wherein the emitter conductive layer extends across each of the plurality of additional trenches.

10. The insulated gate bipolar transistor according to claim 1, wherein:
the plurality of contact regions are formed in a single one of the sidewalls of each respective second type trench.

11. The insulated gate bipolar transistor according to claim 1, wherein:
the plurality of contact regions of the first dopant type are formed in two facing sidewalls of each respective second type trench.

12. The insulated gate bipolar transistor according to claim 1, wherein a width of each of the plurality of mesas is no greater than 0.5 micrometers.

13. The insulated gate bipolar transistor according to claim 1, wherein the insulated gate bipolar transistor is characterized by a lack of a plurality of hole storage regions under the well layer in the plurality of mesas.

14. An insulated gate bipolar transistor, comprising:
a plurality of semiconductor layers that (i) include a well layer that defines a semiconductor surface and (ii) define a plurality of first type trenches and a plurality of second type trenches through the semiconductor surface and into at least the well layer;
a trench material disposed in the plurality of second type trenches;
a plurality of mesas that (i) separate the plurality of first type trenches and the plurality of second type trenches and (ii) each includes a sidewall that faces a corresponding one of the plurality of second type trenches;
a plurality of contact regions (i) of a first dopant type and (ii) formed in one or more of the sidewalls within each respective second type trench of the plurality of second type trenches;
an electrically insulative layer (i) formed over the semiconductor surface and (ii) defines a plurality of openings aligned with the plurality of contact regions; and
an emitter conductive layer formed over the electrically insulative layer, into the plurality of second type trenches, and in direct contact the plurality of contact regions through the plurality of openings.

15. The insulated gate bipolar transistor according to claim 14, further comprising:
a plurality of buffer regions of a second dopant type (i) formed in the plurality of mesas and (ii) extend away from the semiconductor surface into the well layer, wherein the second dopant type and the first dopant type are opposite charge carrier types.

16. The insulated gate bipolar transistor according to claim 14, wherein:
the plurality of semiconductor layers further define a plurality of additional trenches formed through the semiconductor surface into the well layer and aligned the plurality of second type trenches.

17. The insulated gate bipolar transistor according to claim 14; wherein:
the electrically insulative layer isolates the trench material from the plurality of semiconductor layers.

18. The insulated gate bipolar transistor according to claim 14, wherein a width of each of the plurality of mesas is no greater than 0.5 micrometers.

19. The insulated gate bipolar transistor according to claim 14, wherein a width of each of the plurality of mesas is approximately 0.16 micrometers.

20. A method for fabricating an insulated gate bipolar transistor comprising:
forming a plurality of semiconductor layers that includes a well layer that defines a semiconductor surface;
forming a plurality of first type trenches and a plurality of second type trenches (i) that extend through the semiconductor surface and into at least the well layer and (ii) are separated by a plurality of mesas;
filling the plurality of second type trenches with a trench material;
forming a plurality of contact regions (i) of a first dopant type and (ii) in one or more of a plurality of sidewalls within each respective second type trench of the plurality of second type trenches;
forming an electrically insulative layer (i) over the semiconductor surface and (ii) that defines a plurality of openings aligned with the plurality of contact regions; and
forming an emitter conductive layer over the electrically insulative layer, into the plurality of second type trenches, and in direct contact the plurality of contact regions through the plurality of openings.
